(19) United States
(12) Patent Application Publication
(10) Pub. No.: US 2026/0235700 A1
(43) Pub. Date: Aug. 13, 2026

(54) METHOD FOR TESTING A PACKAGING SUBSTRATE, AND APPARATUS FOR TESTING A PACKAGING SUBSTRATE

(71) Applicant: Applied Materials, Inc., Santa Clara, CA (US)

(72) Inventors: Axel WENZEL, Augsburg (DE); Bernhard G. MUELLER, Finsing (DE); Robert TRAUNER, Pliening (DE)

(21) Appl. No.: 19/470,903

(22) PCT Filed: Oct. 18, 2023
(86) PCT No.: PCT/EP2023/079030

§ 371 Date: Sep. 30, 2025

(51) Int. Cl. G01R 31/52; G01R 31/28; G01R 31/305; G01R 31/309

(52) U.S. Cl. CPC G01R 31/52; G01R 31/2801; G01R 31/305; G01R 31/309

(57) ABSTRACT

A method for testing a packaging substrate with at least one electron beam column is provided. The method includes a first test operation, wherein the first test operation includes: positioning the packaging substrate in a vacuum chamber; connecting a voltage source to one or more first contact pads of a first large network of the packaging substrate, the first large network comprising a first plurality of contact pads having a large number of contact pads, the first large network further comprising first electrical interconnect paths for interconnecting the first plurality of contact pads; applying a first electric potential to the one or more first contact pads using the voltage source; charging one or more further networks of the packaging substrate to a second electric potential different from the first electric potential, wherein the one or more further networks comprise a further plurality of contact pads; obtaining information about one or more electric potentials of a second plurality of contact pads comprising the further plurality of contact pads, wherein obtaining the information about one or more electric potentials comprises directing an electron beam of the at least one electron beam column via vector addressing onto each of the second plurality of contact pads and obtaining information about an electric potential of each of the second plurality of contact pads; and determining at least one defect of the packaging substrate based on the information about one or more electric potentials of the second plurality of contact pads.

### FIELD

The present disclosure relates to a method and an apparatus for testing a packaging substrate. More particularly, embodiments described herein relate to the testing of electric interconnections in a packaging substrate such as a panel-level packaging (PLP) substrate or an advanced packaging (AP) substrate by using one or more electron beams, particularly for identifying and characterizing defects such as shorts and/or opens.

### BACKGROUND

In many applications, it is necessary to inspect a substrate to monitor the quality of the substrate. Since defects may occur for example, during the processing of the substrates, e.g. during structuring or coating of the substrates, an inspection of the substrate for reviewing the defects and for monitoring the quality may be beneficial.

Semiconductor packaging substrates and printed circuits boards for the manufacture of complex microelectronic and/or micro-mechanic components are typically tested during and/or after manufacturing for determining defects, such as shorts or opens, in metal paths and interconnects provided at the substrate. For example, substrates for the manufacture of complex microelectronic devices may include a plurality of interconnect paths for connecting semiconductor chips or other electrical devices that are to be mounted on the packaging substrate.

Various methods for testing such components are known. For example, contact pads of a component to be tested may be contacted with a contact probe, in order to determine whether the component is defective or not. Since the components and the contact pads are becoming smaller and smaller due to the progressing miniaturization of components, contacting a multitude of contact pads with a contact probe may be difficult, and there may even be a risk the device to be tested is damaged during the testing.

The complexity of packaging substrates is increasing and design rules (feature size) are decreasing substantially. Contact pads on the surface of the packaging substrates (for later flip chip or other chip mounting) are connected to other contact pads on the packaging substrate to interconnect semiconductor (or other) devices. Standard methods like electrical-mechanical probing for electrical tests cannot satisfy the requirements of volume production testing, as the throughput decreases (higher number of test points) and contacting reliability decreases (smaller contact size). Beyond the reduced size and the problem of potentially damaging the contact pads, the topography of the packaging substrates results in difficulties for other test methods, like test methods utilizing capacitive detectors or electrical field detectors, because such methods beneficially have a small mechanical spacing.

Accordingly, it would be beneficial to provide testing methods and testing apparatuses that are suitable for reliably and quickly testing complex microelectronic devices, particularly packaging substrates such as AP substrates and PLP substrates.

### SUMMARY

In light of the above, a method and apparatus for testing a packaging substrate are provided according to the independent claims. Further aspects, advantages, and beneficial features are apparent from the dependent claims, the description, and the accompanying drawings.

According to an embodiment, a method for testing a packaging substrate with at least one electron beam column is provided. The method includes a first test operation. The first test operation includes positioning the packaging substrate in a vacuum chamber. The first test operation includes connecting a voltage source to one or more first contact pads of a first large network of the packaging substrate. The first large network includes a first plurality of contact pads having a large number of contact pads. The first large network further includes first electrical interconnect paths for interconnecting the first plurality of contact pads. The first test operation includes applying a first electric potential to the one or more first contact pads using the voltage source. The first test operation includes charging one or more further networks of the packaging substrate to a second electric potential different from the first electric potential. The one or more further networks include a further plurality of contact pads. The first test operation includes obtaining information about one or more electric potentials of a second plurality of contact pads including the further plurality of contact pads. Obtaining the information about one or more electric potentials includes directing an electron beam of the at least one electron beam column via vector addressing onto each of the second plurality of contact pads and obtaining information about an electric potential of each of the second plurality of contact pads. The first test operation includes determining at least one defect of the packaging substrate based on the information about one or more electric potentials of the second plurality of contact pads.

According to an embodiment, an apparatus configured for testing a packaging substrate is provided. The apparatus includes a stage for arranging the packaging substrate. The apparatus includes at least one electron beam column for providing an electron beam. The apparatus includes a voltage source configured to be connected to a contact pad of the packaging substrate. The apparatus includes a computer-readable medium containing a program for testing the packaging substrate, which, when executed by a processor, performs a method according to any of the embodiments described herein.

According to an embodiment, a non-transitory computer-readable medium is provided. The non-transitory computer-readable medium includes instructions, which, when executed by a processor of an apparatus configured for testing a packaging substrate, cause the apparatus to perform a method according to any of the embodiments described herein.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus and a method for manufacturing the apparatuses and devices described herein. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic sectional view of an apparatus for testing a packaging substrate in accordance with testing methods described herein;

FIG. 2 shows a flowchart of a method of testing a packaging substrate according to embodiments described herein;

FIGS. 3A-3C schematically illustrate the testing of networks in packaging substrates in accordance with methods described herein;

FIG. 4 schematically illustrates the addressing of a plurality of contact pads using an electron beam for testing a packaging substrate in accordance with methods described herein;

FIG. 5 shows a flowchart of a further method of testing a packaging substrate according to embodiments described herein;

FIGS. 6A and 6B show enlarged sectional views of packaging substrates during testing according to embodiments described herein; and

FIGS. 7A-7D show enlarged sectional views of examples of packaging substrates that may be tested according to the methods described herein.

### DETAILED DESCRIPTION

Reference will now be made in detail to the various exemplary embodiments, one or more examples of which are illustrated in each figure. Each example is provided by way of explanation and is not meant as a limitation. For example, features illustrated or described as part of one embodiment can be used on or in conjunction with other embodiments to yield yet further embodiments. The intention is that the present disclosure includes such modifications and variations.

Within the following description of the drawings, the same reference numbers refer to the same components. Only the differences with respect to the individual embodiments are described. The structures shown in the drawings are not necessarily depicted true to scale but rather serve for the better understanding of the embodiments.

The complexity of packaging substrates has been increasing for years, with the aim of reducing the space requirements of semiconductor packages. For reducing the manufacturing costs, packaging techniques were proposed, such as 2.5D ICs, 3D-ICs, and wafer-level packaging (WLP), e.g. fan-out WLP. In WLP techniques, the integrated circuit is packaged before dicing. A “packaging substrate” as used herein relates to a packaging substrate configured for an advanced packaging technique, particularly a WLP-technique or a panel-level-packaging (PLP)-technique.

“2.5D integrated circuits” (2.5D ICs) and “3D integrated circuits” (3D ICs) combine multiple dies in a single integrated package. Here, two or more dies are placed on a packaging substrate, e.g. on a silicon interposer or a panel-level-packaging substrate. In 2.5D ICs, the dies are placed on the packaging substrate side-by-side, whereas in 3D ICs at least some of the dies are placed on top of each other. The assembly can be packaged as a single component, which reduced costs and size as compared to a conventional 2D circuit board assembly.

A packaging substrate typically includes a plurality of device-to-device electrical interconnect paths for providing electrical connections between the chips or dies that are to be placed on the packaging substrate. The device-to-device electrical interconnect paths may extend through a body of the packaging substrate in a complex connection network. The electrical interconnect paths may particularly extend vertically (perpendicular to the surface of the packaging substrate) and/or horizontally (parallel to the surface of the packaging substrate) with end points (referred to herein as contact pads or contact points) exposed at the surface of the packaging substrate.

An advanced packaging (AP) substrate provides the device-to-device electrical interconnect paths on or within a wafer, such as a silicon wafer. For example, an AP substrate may include Through Silicon Vias (TSVs), e.g., provided in a silicon interposer, other conductor lines extending through the AP substrate. A panel-level-packaging (PLP) substrate is provided from a compound material, for example material of a printed circuit board (PCB) or another compound material, including, for example ceramics and glass materials.

PLP substrates are manufactured that are configured for the integration of a plurality of devices (e.g., chips/dies that may be heterogeneous, e.g. may have different sizes and configurations) in a single integrated package. Further, AP substrates may be combined on a PLP substrate. A panel-level substrate typically provides sites for a plurality of chips, dies, or AP substrates to be placed on a surface thereof, e.g. on one side thereof or on both sides thereof, as well as a plurality of device-to-device electrical interconnect paths extending through a body of the PLP substrate.

Notably, the size of a panel-level-substrate is not limited to the size of a wafer. For example, a panel-level-substrate may be rectangular or have another shape. Specifically, a panel-level-substrate may provide a surface area larger than the surface area of a typical wafer, e.g., 1000 cm² or more. For example, the panel-level substrate may have a size of 30 cm×30 cm or larger, 60 cm×30 cm or larger, 60 cm×60 cm or larger. A packaging substrate, such as a PLP substrate, may include a plurality of device-to-device connections, e.g. 5,000 or more, 10,000 or more, 20,000 or more, or even 50,000 or more. The connections may include Through Silicon Vias (TSVs), e.g., provided in a silicon interposer, other conductor lines extending through the packaging substrate, and/or may include multi-die interconnect bridges that may be embedded in the packaging substrate. The packaging substrate may be a multi-layer substrate including electrical interconnections in a plurality of layers arranged on top of each other, e.g. in a layer stack.

The present disclosure relates to methods and apparatuses for testing packaging substrates that are configured for the integration of a plurality of devices in one integrated package, and include device-to-device electrical interconnect paths. According to embodiments of the present disclosure, a test system, test apparatus, or test method may detect and/or classify defective electrical interconnect paths in a packaging substrate, such as opens, shorts, leakage defects, or others. A contact pad pitch of 60 μm or below or even about 10 μm or below is difficult for mechanical probing of a multitude of contact pads.

According to embodiments of the present disclosure, electron beam testing and/or electron beam review provides for testing of contact pads, wherein at least one of the contact pads of the packaging substrate has a diameter of 60 μm or less, particularly of 25 μm or less, or even 10 μm or less. According to some embodiments, which can be combined with other embodiments described herein, a contact pad can have a three-dimensional topography, for instance a substantially semi-spherical shape. Additionally, or alternatively, contact pads may have one or more other shapes, such as an essentially rectangular shape. According to embodiments, voltage contrast testing may be used for testing contact pads of the packaging substrate.

A contact pad may be understood as a surface contact point, particularly as an end point of an electrical interconnect path, the end point being exposed on a surface of the packaging substrate, such that an electron beam can be directed on the contact pad for charging or probing the electrical interconnect path. A contact pad can be configured to electrically contact a chip, a die, a smaller package, or other electrical components like capacitors, resistors, coils, or the like, that is to be placed on the surface of the packaging substrate, e.g. via soldering. Electrical components may also include active electrical components, such as transformers changing the voltage in a region of the package. In some embodiments, the contact pads may be or may include solder bumps.

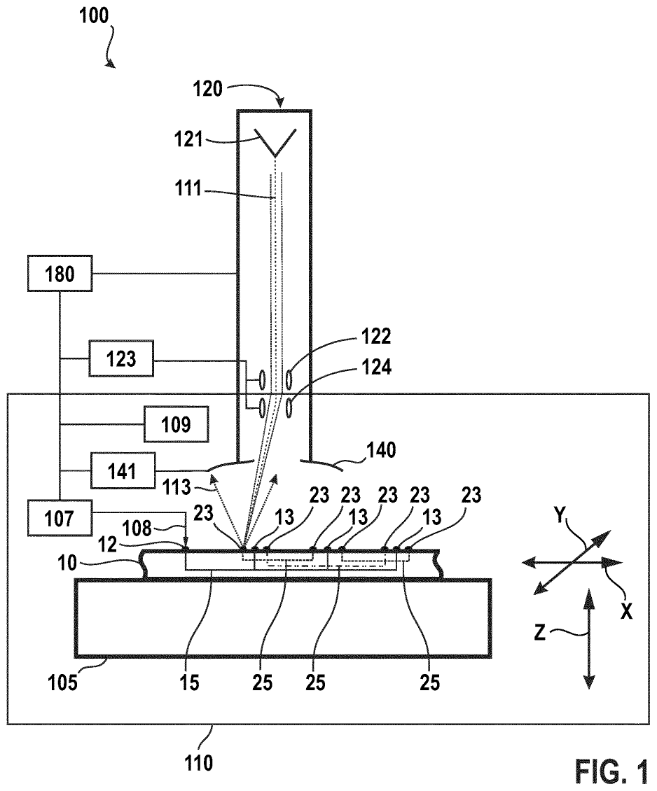

FIG. 1 shows an apparatus 100 for testing a packaging substrate 10 according to embodiments described herein in a schematic sectional view. The apparatus 100 includes a vacuum chamber 110 that may be a testing chamber specifically configured for testing or that may be one vacuum chamber of a larger vacuum system, e.g. a processing chamber of a packaging substrate manufacturing or processing system.

According to embodiments and as schematically depicted in FIG. 1, a packaging substrate 10 includes a substrate body and a plurality of electrical networks, the plurality of electrical networks particularly including a first large network and one or more further networks. In particular, the first large network includes a first plurality of contact pads 13 at a surface of the packaging substrate 10, and first electrical interconnect paths 15 for interconnecting the first plurality of contact pads 13. The one or more further networks include a further plurality of contact pads 23 at the surface of the packaging substrate 10. Each of the one or more further networks may further include one or more further electrical interconnect paths 25 for electrically interconnecting contact pads of a network of the one or more further networks. For instance, FIG. 1 shows three further networks, each having two contact pads 23 interconnected by a further electrical interconnect path 25. The electrical interconnect paths of the packaging substrate 10 depicted in FIG. 1 extend only between the contact pads that are arranged at a top surface of the packaging substrate, but the present disclosure is not limited to such electrical interconnect paths. The electrical interconnect paths may be provided in a complex arrangement of vias, pillars, and/or conductor lines extending through the packaging substrate and having a plurality of contact pads on one or more sides of the packaging substrate.

The contact pads and electrical interconnect paths of the plurality of electrical networks of the packaging substrate 10 may be provided and arranged for connection to a plurality of devices, e.g. chips or dies, that are to be placed on the packaging substrate 10. In FIG. 1, a few device-to-device electrical interconnect paths are exemplarily depicted, but the packaging substrate 10 may include thousands or tens of-thousands of such device-to-device electrical interconnect paths that are typically electrically isolated from each other, if no short exists between two electrical interconnect paths.

According to embodiments of the present disclosure, packaging substrates with at least one large network are tested, particularly with a first large network as described herein. According to embodiments, a large network, in particular the first large network or a second large network as referred to herein, has a large number of contact pads. Specifically, in embodiments, a large network includes at least 10 contact pads, particularly at least 500 contact pads, or more particularly at least 1,000 contact pads. In some embodiments, the packaging substrate may have at least 5,000 contact pads, particularly at least 10,000, at least 50,000 or at least 100,000 contact pads on a first side of the packaging substrate to be tested. A small network as referred to herein is smaller than a large network. According to embodiments, the packaging substrate has one or few large networks each with a large number of contact pads, and many small networks each with a small number of contact pads. For instance, according to non-limiting examples, a packaging substrate may have more than 150,000 contact pads on a first side of the packaging substrate, wherein said contact pads pertain to more than 15,000 different networks having at least one contact pad on the first side. In a particular example, more than 99% of the networks have less than 10 contact pads on the first side, wherein most networks have only one or two contact pads on the first side. Meanwhile, less than 30 networks have more than 10 contact pads on the first side, but account for more than 80% of the contact pads on the first side. Less than 10 networks may have more than 500 contact pads on the first side, but may still account, for example, for over 80% of the contact pads on the first side. For instance, the two largest networks each may have more than 50,000 contact pads on the first side.

According to embodiments described herein, the packaging substrate 10 is positioned in the vacuum chamber 110, particularly on a stage 105 of the apparatus 100. The stage 105 can be movable, particularly in the z-direction (i.e., in a direction perpendicular to the stage surface) and/or in the x-and y-directions (i.e., in the plane of the stage surface). The stage 105 is provided within the vacuum chamber and is configured to support the packaging substrate 10.

In embodiments, the apparatus 100 includes a voltage source 107 configured to be connected, particularly electrically connected, to the packaging substrate 10, for instance to one or more first contact pads 12 of the first plurality of contact pads of the first large network. The voltage source 107 may be configured to connect to a network, such as the first large network, by mechanically contacting the one or more first contact pads 12, particularly using a mechanical contact device 108. For example, a mechanical contact device 108 of the voltage source 107 may include a needle for mechanically contacting the one or more first contact pads 12. The voltage source 107 may include an actuator for adjusting a position of the mechanical contact device 108 for contacting the packaging substrate 10 at different positions of the packaging substrate 10. In embodiments, the voltage source 107 may be configured to provide voltages at least in the range of −20 to +20V, particularly at least in the range of −15 V to +15 V, or more particularly at least in the range of −10 V to +10 V. In embodiments, the voltage source 107 is configured to apply a potential to a network connected to the voltage source 107, for instance to the first large network. The voltage source 107 may be used particularly for a fast application of a potential to one or more large networks such as the first large network. A large network may otherwise have long charging times due to a high capacitance of a large network. For instance, using a focused electron beam for charging the large network may take a longer time than charging via the voltage source 107. In FIG. 1, the voltage source 107 is electrically connected via a needle to a first contact pad 12 of the first plurality of contact pads 13. The voltage source 107 charges the first large network to a different potential as compared to the further networks of the packaging substrate 10.

According to embodiments, an electron beam column 120 may be provided on a first side of the stage 105. In some embodiments, which can be combined with other embodiments described herein, the electron beam column 120 may have an electron source 121 for generating an electron beam 111, as well as beam-optical elements, such as one or more deflectors and/or an objective lens, for directing the electron beam onto a substrate placed on the stage 105, such as the packaging substrate 10. The objective lens may be an electrostatic objective lens, a magnetic objective lens, or a magnetic-electrostatic objective lens. In some embodiments, directing the electron beam 111 onto a contact pad includes focusing the electron beam 111 onto the contact pad, e.g. with a beam probe diameter on the packaging substrate of 30 μm or less, particularly 10 μm or less. A focusing of the charging electron beam on the packaging substrate, e.g. with the objective lens, can prevent the charging of substrate surface areas different from the surface contact pads and can provide accurate testing results.

In some embodiments, the one or more deflectors include a main deflector 122 and a subdeflector 124. The main deflector may be a magnetic main deflector. The subdeflector may be an electrostatic subdeflector. In embodiments, a magnetic main deflector may provide a deflection over a wide surface area of the packaging substrate. For example, the magnetic main deflector may be configured for deflecting an electron beam over a surface area of the packaging substrate of at least 50 mm×50 mm, particularly at least 100 mm×100 mm, and/or maximum 250 mm×250 mm, particularly maximum 200 mm×200 mm or maximum 150 mm×150 mm. An electrostatic subdeflector may provide deflection over a smaller surface area of the packaging substrate than the magnetic main deflector. The magnetic main deflector may be slower to deflect the electron beam than the electrostatic subdeflector, particularly due to a self-inductance of the magnet main deflector.

In some embodiments, the apparatus 100 may include a deflector controller 123 connected to the one or more deflectors of the electron beam column 120. The one or more deflectors may be configured to position the electron beam 111 at different positions on the surface of the packaging substrate 10. It should be understood that one or more deflectors may be controlled by the deflector controller 123 in a raster scanning mode or, alternatively, to position the electron beam at distinct positions via vector addressing. In particular, the deflector controller 123 may control the one or more deflectors to raster scan the electron beam over at least a portion of the surface of the packaging substrate. Alternatively, the deflector controller 123 may control the one or more deflectors, such as a magnetic main deflector and an electrostatic subdeflector, to position the electron beam 111 via vector addressing to a certain position, for instance to a known position of a contact pad of a packaging substrate. In particular, positioning the electron beam on contact pads by vector addressing as used herein, may be understood as positioning the electron beam sequentially to a position of a contact pad and next to a further position of a further contact pad, specifically without raster scanning a region between the contact pad and the further contact pad. Positions of contact pads may be predetermined, for instance from a construction file of the packaging substrate, which may for example provide a map or table of including information on networks, contact pads and/or respective positions. The electron beam may be positioned to the contact pads based on the predetermined positions of the contact pads and based on a detection of one or more marks or other distinctive features on the packaging substrate suitable for coordinate system alignment. Directing the electron beam onto contact pads using vector addressing may provide a fast testing of contact pads, particularly faster than raster scanning a region including a contact pad and a portion of the substrate body. Further, vector addressing may reduce the overall charge accumulated on the packing substrate.

In some embodiments, the deflector controller 123 may be configured to control the one or more deflectors such that the electron beam is sequentially directed to pairs or groups of contact pads for testing respective device-to-device electrical interconnect paths extending between the respective contact pads. This allows a quick and reliable test of a plurality of electrical interconnect paths extending through the packaging substrate, particularly for small networks of the packaging substrate according to some embodiments described herein.

As shown for example in FIG. 1, electron beam 111 is directed via vector addressing onto one of the further plurality of contact pads 23 of a further network different from the first large network. Signal electrons 113 emitted from the further contact pad 23 are detected using an electron detector 140 for testing the packaging substrate 10. For instance, the packaging substrate 10 may be tested with respect to a possible short between the first large network and the further network which includes the contact pad probed by the electron beam 111. The signal electrons 113 may be secondary electrons and/or backscattered electrons. In some embodiments described herein, the electron beam may be further directed to contact pads of the first plurality of contact pads 13 for testing the packaging substrate 10.

In particular, by detecting the signal electrons 113 emitted upon impingement of the electron beam 111 on a contact pad of the packaging substrate 10 (particularly, by determining the number or energy of the signal electrons 113 that depends on the electric potential of the contact pad probed by the electron beam 111), it can be determined in a “voltage contrast measurement” whether a defect related to the probed contact pad is present in the packaging substrate 10. Specifically, defective connections in the packaging substrate can be determined and classified, e.g. in open and/or short defects.

In some embodiments, which can be combined with other embodiments described herein, one or more networks extending between surface contacts on different sides of the substrate are inspected. In yet further embodiments, one or more networks extending between and including contact pads on a first side of the substrate, one or more further networks extending between and including contact pads on a second side of the substrate, and/or one or more yet further networks extending between and including contact pads on different sides of the substrate are inspected. For example, one or more electron beam columns may be arranged on both sides of the substrates (not shown in the figures), such that contact pads on both sides of the substrate can be probed using electron beams.

In embodiments, the apparatus 100 further includes an electron detector 140 for detecting signal electrons 113 emitted upon impingement of the second electron beam on the packaging substrate. In some embodiments, which can be combined with other embodiments described herein, the electron detector 140 includes an Everhard-Thornley detector. An energy filter for the signal electrons 113 may be arranged in front of the electron detector 140, particularly in front of the Everhard-Thornley detector. The energy filter may include a grid electrode configured to be set on a predetermined potential. The energy filter may allow the suppression of low-energy signal electrons. The energy filter may suppress signal electrons that are irrelevant for voltage contrast measurements to be conducted. In some implementations, the energy filter may suppress signal electrons emitted from uncharged surface areas and may only let through signal electrons emitted from a charged surface contact pad. Accordingly, the signal current detected by the electron detector may depend on the energy of the signal electrons, which may provide information about an electric potential of a probed contact pad.

According to embodiments, the apparatus 100 may further include an analysis unit 141 connected to the electron detector 140, as illustrated e.g. in FIG. 1. The analysis unit 141 may be configured to determine information about an electric potential of a contact pad probed by the electron beam based on a signal from the electron detector 140, the signal being detected while the electron beam probes the contact pad. In some embodiments, determining the information about an electric potential of the contact pad may include calculating an electric potential of the contact pad based on the signal from the electron detector 140. According to some embodiments, the analysis unit 141 is configured for determining a defect based on the determined information about one or more electric potentials of probed contact pads in accordance with methods described herein. Optionally, the analysis unit 141 may be configured to classify any detected defect, for instance classifying a defect as a short or an open. An “open” as used herein is understood as an open electrical interconnect path that does not actually electrically connect two or more contact pads, although said electrical interconnect path should connect the two or more contact pads, particularly according to a design of the packaging substrate. A “short” is understood as an electrical connection between two electrical interconnect paths that are actually to be electrically separated.

As schematically depicted in FIG. 1, the apparatus 100 includes an electron source 121. The electron source 121 is connected to a power supply. The power supply can provide a high-voltage to the electron source for emitting the electron beam 111, i.e. the primary electron beam, from the electron source 121. According to some embodiments, which can be combined with other embodiments described herein, the voltage provided by the power supply can be varied to change the energy of the electron beam and, thus, the landing energy of the electron beam on the packaging substrate. According to some embodiments, which can be combined with other embodiments described herein, one or more power supplies can be connected to various components of the electron beam column. For example, power supplies can be connected to the electron source, to an extractor of the electron source, to an anode of the electron source, to a deceleration electrode configured to decelerate the electrons before impingement on the packaging substrate, and/or to the stage 105. The landing energy of the electron beam on the packaging substrate is determined by the potential difference between the potential of the emitter tip of the electron source and the potential of the packaging substrate or the potential of the stage 105, respectively. Accordingly, one or more power supplies to vary the landing energy of the electron beam can be provided.

According to some embodiments, the apparatus 100 may include a device 109 for charging a plurality of networks of the packaging substrate 10, particularly for simultaneously charging all networks having a contact pad on a first side of the packaging substrate, the first side being arranged for exposure to the electron beam 111. The device 109 for charging the plurality of networks may be configured for contactless charging of the plurality of networks. For instance, the device 109 for charging the plurality of networks may include or be a flood gun for electron exposure of the packaging substrate 10, a vacuum ultraviolet (VUV) lamp for irradiating the packaging substrate with vacuum ultraviolet light, an electron beam device or an ion beam device. The device 109 may be at least partially arranged in the vacuum chamber 110.

In embodiments, the apparatus 100 includes a controller 180, as shown for example in FIG. 1. According to some embodiments, which can be combined with other embodiments described herein, the controller can be connected to one or more of the components of the apparatus 100 for testing of a packaging substrate. The controller 180 can be connected to and/or configured to control the voltage source 107, the device 109 for charging a plurality of networks of the packaging substrate 10, the deflector controller 123, the analysis unit 141, one or more power supplies, and the stage 105. The controller 180 may also be connected to the electron detector 140.

The controller 180 includes a central processing unit (CPU), a memory and, for example, support circuits. To facilitate control of the apparatus for testing packaging substrates, the CPU may be one of any form of general purpose computer processor that can be used in an industrial setting for controlling various chambers and sub-processors. The memory is coupled to the CPU. The memory, or a computer readable medium, may be one or more readily available memory devices such as random access memory, read only memory, hard disk, or any other form of digital storage either local or remote. The support circuits may be coupled to the CPU for supporting the processor in a conventional manner. These circuits include cache, power supplies, clock circuits, input/output circuitry, related subsystems, and the like. Inspecting process instructions are generally stored in the memory as a software routine typically known as a recipe. The software routine may also be stored and/or executed by a second CPU (not shown) that is remotely located from the hardware being controlled by the CPU. The software routine, when executed by CPU, transforms the general purpose computer into a specific purpose computer (controller) that controls the apparatus operation such as that for controlling the one or more deflectors, the landing energy, the stage positioning, the device for charging a plurality of networks and/or the voltage source during the testing operation. Although the method and/or process of the present disclosure is discussed as being implemented as a software routine, some of the method steps that are disclosed therein may be performed in hardware as well as by the software controller. As such, embodiments of the invention may be implemented in software as executed upon a computer system, and hardware as an application specific integrated circuit or other type of hardware implementation, or a combination of software and hardware.

The controller may execute or perform a method of testing a packaging substrate with at least one electron beam column as described herein. According to an embodiment, an apparatus for testing of packaging substrates with any of the methods described herein is provided. The apparatus may include the controller 180. The controller includes a processor and memory storing instructions (or a program) that, when executed by the processor, cause the apparatus to perform a method according to embodiments of the present disclosure.

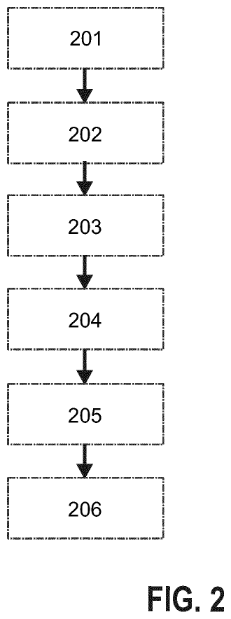

According to embodiments of the present disclosure, a method for testing a packaging substrate with at least one electron beam column is provided. The method includes at least one test operation, particularly a first test operation, for instance in accordance with a method as illustrated in FIG. 2. In embodiments, the method includes positioning the packaging substrate in a vacuum chamber (block 201 in FIG. 2), particularly on a stage 105 of an apparatus 100 for testing a packaging substrate 10 as described herein and as illustrated for example, in FIG. 1. The packaging substrate 10 may be placed on the stage 105 and positioned for testing in the apparatus 100. In some embodiments, the packaging substrate may have a first side with a surface area of more than 500 cm², particularly of more than 1,000 cm² or more than 2,000 cm², and/or less than 15,000 cm², particularly less than 10,000 cm².

In embodiments, the method includes connecting a voltage source 107 to one or more first contact pads 12 of a first large network of the packaging substrate 10 (block 202 in FIG. 2). The first large network includes a first plurality of contact pads 13 having a large number of contact pads as described herein. The first large network further includes first electrical interconnect paths 15 for interconnecting the first plurality of contact pads 13. For instance, the first large network may be a network configured for providing connections to a ground or to a power supply for the devices to be mounted on the packaging substrate 10. In some embodiments, the first plurality of contact pads 13 includes at least 10 contact pads, particularly at least 500 contact pads, more particularly at least 1,000 contact pads. In particular, the first plurality of contact pads has at least 10 contact pads, particularly at least 500 contact pads or at least 1,000 contact pads, on the same side of the packaging substrate as the further plurality of contact pads.

According to some embodiments, connecting the voltage source 107 to the one or more first contact pads 12 of the first large network includes providing a mechanical contact between the voltage source 107 and the one or more first contact pads 12. The mechanical contact may be provided for instance via a mechanical contact device 108 including e.g. a needle of the voltage source 107. The mechanical contact device 108 can be positioned for contacting the one or more first contact pads 12 to provide an electrical connection between the voltage source 107 and the one or more first contact pads 12.

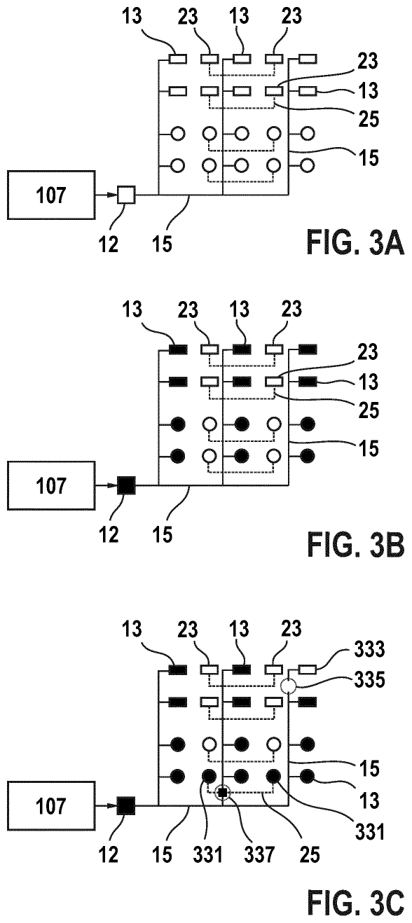

Referring to FIG. 3A, a schematic illustration of a plurality of networks of a packaging substrate is shown. Although only a few contact pads and networks are shown for illustrative purposes, it is understood that a packaging substrate may include far more networks and contact pads as described herein. In FIG. 3A, a first large network includes a first plurality of contact pads 13, the first plurality of contact pads 13 including a first contact pad 12 which is mechanically contacted by a voltage source 107. The first plurality of contact pads 13 are electrically interconnected via first electrical interconnect paths 15. As shown for example in FIG. 3A, the contact pads of the packaging substrate may be irregularly positioned and/or include contact pads of different sizes and/or shapes. The packaging substrate shown in FIG. 3A additionally includes several further networks having a further plurality of contact pads 23. Each of the further networks has at least one further electrical interconnect path 25 electrically interconnecting further contact pads of the respective further network. In further embodiments, one or more of the further networks of the packaging substrate may have only one contact pad, for example only one contact pad on a first side of the packaging substrate. As another example, a network may have only one contact pad if an additional layer is to be added on the packaging substrate to connect an additional electrical interconnect path to that contact pad. In FIG. 3A, the first electrical interconnect paths 15 are fabricated to be electrically isolated from the further electrical interconnect paths 25. For instance, the first electrical interconnect paths 15 and further electrical interconnect paths 25 may be arranged in different layers of the packaging substrate and/or arranged in the same layer of the packaging substrate such that the interconnect paths do not contact each other.

According to embodiments, the method includes applying a first electric potential to the one or more first contact pads 12 using the voltage source 107 (block 203 in FIG. 2). Applying the first electric potential to the one or more first contact pads 12 can charge the first large network to the first electric potential. In particular, all electrical interconnect paths of the first large network and all contact pads of the first large network, which are electrically connected to the one or more first contact pads 12, are charged to the first potential. Contact pads and electrical interconnect paths of the first large network, which are electrically separated from the one or more first contact pads 12 due to an open defect of the first large network, are not charged. Charging the first large network using the voltage source 107 can provide fast charging of the first large network as compared to charging the first large network using e.g. the electron beam 111 of the at least one electron beam column 120.

In embodiments, the method includes charging one or more further networks of the packaging substrate 10 to a second electric potential (block 204 in FIG. 2), the second electric potential being different from the first electric potential. The one or more further networks include a further plurality of contact pads 23 (see for example FIG. 1 or 3A). In some embodiments, the one or more further networks are charged to the second electric potential by contactless charging the one or more further networks to the second electric potential. For example, a device 109 for charging a plurality of networks as described herein may be used for charging the one or more further networks. In some embodiments, contactless charging of the one or more further networks is performed by exposing the further plurality of contact pads 23 of the one or more further networks to at least one of vacuum ultraviolet light (VUV), electrons of a flood gun, an electron beam, or an ion beam. In some embodiments, charging the one or more further networks may be performed before charging the first large network with the voltage source 107. In further embodiments, the one or more further networks may be charged after the first large network. In particular, the voltage source 107 may maintain the first large network at the first electric potential, while the one or more further networks is contactlessly charged. As used herein, charging a network to an electrical potential may particularly include adding charge to the network or removing charge from the network, specifically adding or removing electrons to or from the network.

In embodiments, the second electric potential is different from the first electric potential. In particular, the first electric potential and the second electric potential may be set such that the difference in potential may be sufficient for distinguishing between a contact pad at the first electric potential and another contact pad at the second electric potential, particularly in voltage contrast measurements using an apparatus 100 as described herein. For example, the difference (voltage) between the first electric potential and the second electric potential may be at least 1 V, particularly at least 2 V or at least 3 V, and/or maximum 20 V, particularly maximum 15 V or maximum 10V, for example approximately 5 V. In a non-limiting example, the voltage source 107 may be used to apply a first electric potential of 0 V to the first large network, and the one or more further networks may be contactlessly charged to a second electric potential of +5 V. In another example, a first electric potential of −5 V may be applied to the first large network, and the one or more further networks may be charged to a second electric potential of 0 V.

For example, FIG. 3B illustrates the networks shown in FIG. 3A after a first electric potential is applied to the first large network, and after the further networks are contactlessly charged to a second electric potential different from the first electric potential. With no defect present, in FIG. 3B each of the first plurality of contact pads 13 is charged by the voltage source 107 to the first electric potential. Further, each contact pad of the further plurality of contact pads 23 is charged to the second electric potential. Contact pads at the first electric potential are represented in FIGS. 3B and 3C as filled circles or rectangles, while contact pads at the second electric potential are represented by empty circles or rectangles.

FIG. 3C illustrates the same networks as shown in FIG. 3B, however with defects in the packaging substrate. In particular, the packaging substrate has a short 337 between a first electrical interconnect paths 15 of the first large network and a further electrical interconnect path 25 of a further network. Due to the short 337, the contact pads 331 of the further network are electrically connected to the first large network and therefore charged to the first electric potential. Further, the packaging substrate shown in FIG. 3C has an open 335 in a first electrical interconnect path 15 of the first large network such that the contact pad 333 is electrically isolated from the rest of the first large network. Thus, the contact pad 333 is not connected to the voltage source 107, but contactlessly charged to the second electric potential.

According to embodiments of the present disclosure, the method includes obtaining information about one or more electric potentials of a second plurality of contact pads (block 205 in FIG. 2). The information about the one or more electric potentials may be obtained via a voltage contrast measurement for each contact pad of the second plurality of contact pads using the electron beam 111. In embodiments, the second plurality of contact pads includes the further plurality of contact pads 23 of the one or more further networks. In some embodiments, the one or more further networks may be one or more networks with a risk for a short to the first large network. Information about the one or more electric potentials of the further plurality of contact pads 23 may be used, for example, for determining a short between the first large network and one or more of the further networks, particularly as described in more detail below.

In some embodiments, the second plurality of contact pads includes the first plurality of contact pads 13, particularly the first plurality of contact pads and the further plurality of contact pads 23. Based on the information about one or more electric potentials of the first plurality of contact pads 13, an open in the first large network may be determined. In further embodiments, the second plurality of contact pads includes all contact pads of the packaging substrate 10 arranged on the same side of the packaging substrate as the further plurality of contact pads 23. In even further embodiments, the second plurality of contact pads includes all contact pads of the packaging substrate connected to electrical interconnect paths, particularly such that 100% of electrical interconnect paths of the packaging can be tested for defects. The costs of ownership of device packages including the chips etc., such as processors, memories, or the like (microelectronic devices), is mainly determined by the highly integrated microelectronic devices. Accordingly, mounting a non-defective microelectronic device to a defective packaging substrate is disadvantageous with respect to manufacturing cost. A fully non-defective packaging substrate is desirable before mounting of the microelectronic devices. In some embodiments, the second plurality of contact pads may include all contact pads of the packaging substrate.

According to some embodiments of the present disclosure, the second plurality of contact pads may be provided on the surface of the packaging substrate in an arrangement different from a square lattice arrangement. In some embodiments, the second plurality of contact pads may by irregularly arranged. It should be understood that an arrangement of the second plurality of contact pads different from a square lattice arrangement does not exclude that some contact pads of the second plurality of contact pads may be arranged in a square lattice. Similarly, in an irregular arrangement, some of the contact pads may be regularly arranged. Probing such arrangements of the second plurality of contact pads using an electron beam may, for instance, particularly benefit from vector addressing of the contact pads and/or deflection of the electron beam using a main deflector and a subdeflector, e.g. with respect to an increased speed of probing each of the second plurality of contact pads and/or with respect to avoiding charging of the substrate body.

In embodiments, obtaining the information about one or more electric potentials includes directing an electron beam 111 of the at least one electron beam column 120 onto each of the second plurality of contact pads and obtaining information about an electric potential of each of the second plurality of contact pads. The electron beam 111 is directed onto the contact pads via vector addressing. In particular, the electron beam 111 is sequentially positioned on different contact pads of the second plurality of contact pads, specifically by positioning the electron beam 111 to a position of a contact pad and subsequently to a further position of another contact pad. In particular, the electron beam is directed to the positions of the contact pads specifically based on vector positions of the contact pads, particularly without rastering the electron beam over surface areas of the packaging substrate.

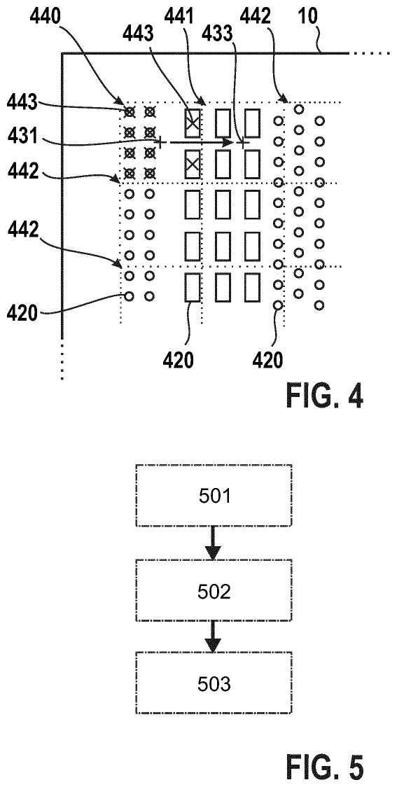

According to some embodiments, the at least one electron beam column 120 includes a main deflector 122 and a subdeflector 124, particularly a magnetic main deflector and an electrostatic subdeflector. Obtaining information about one or more electric potentials of the contact pads may include dividing a surface area of the packaging substrate, the surface area including the second plurality of contact pads 420, into a plurality of subfields 441. For example, FIG. 4 schematically illustrates a portion of a surface of a packaging substrate 10 with contact pads of a second plurality of contact pads 420 on the surface of the packaging substrate 10. A surface area of the packaging substrate 10, wherein the surface area includes the second plurality of contact pads 420 and wherein the surface area is within the deflection range of the main deflector 122, is divided into a plurality of subfields 441. In embodiments, each of the plurality of subfields 441 has a size of minimum 0.1 mm², and/or maximum 30 mm², particularly maximum 25 mm², e.g. approximately 16 mm².

In embodiments, obtaining information about one or more electric potentials of a second plurality of contact pads further includes sequentially directing the electron beam to each of the plurality of subfields using the main deflector. When the electron beam is positioned in a subfield by the main deflector, the electron beam is directed using the subdeflector to each contact pad of the second plurality of contact pads within the subfield for obtaining information about the electric potential of each contact pad in the subfield. For example, the main deflector may deflect the electron beam to a subfield, particularly to a center of the subfield. The subdeflector may direct the electron beam onto each of the second plurality of contact pads within the subfield by sequentially deflecting the electron beam to the positions (vector positions) of each of the second plurality of contact pads within the subfield. When the electron beam is directed onto a contact pad of the second plurality of contact pads, particularly for a pulsed exposure of the contact pad, information about the electric potential of that contact pad may be obtained as described herein. After having obtained the information about the electric potential of each contact pad of the second plurality of contact pads within the subfield, the main deflector may deflect the electron beam to a next subfield. The subdeflector may then deflect the electron beam to address each of the second plurality of contact pads within said next subfield. The main deflector and the subdeflector may proceed accordingly for a plurality of subfields.

For instance, in FIG. 4, the electron beam is first positioned by the main deflector 122 to a first subfield 440. Specifically, the main deflector 122 may direct the electron beam to a main deflection position 431 which is central in the first subfield 440. The subdeflector 124 sequentially directs the electron beam to subdeflection positions 443 in the first subfield 440 (marked by an “x” in FIG. 4, only marked in the first subfield 440) for vector addressing of the contact pads of the second plurality of contact pads 420 within the first subfield 440. After having obtained the information about the one or more electric potentials for each of the second plurality of contact pads 420 to be probed in the first subfield 440, the main deflector 122 changes the main deflection position 431 of the electron beam to a further main deflection position 433 of a second subfield 441. The subdeflector 124 then sequentially directs the electron beam via vector addressing to each contact pad of the second plurality of contact pads 420 in the second subfield 441. The main deflector and the subdeflector may further proceed accordingly for the further subfields 442 to obtain information about the one or more electric potentials for each one of the second plurality of contact pads 420, particularly for all contact pads on the surface area.

According to embodiments, the electron beam 111 is directed onto each contact pad of the second plurality of contact pads for a pulsed exposure of the contact pad to the electron beam for obtaining the information about the electric potential of the contact pad. For example, a pulse duration of the pulsed exposure may be more than 50 ns, particularly more than 100 ns, and/or less than 500 ns, particularly less than 400 or less than 300 ns, for instance approximately 200 ns. In some embodiments, the pulsed exposure of a contact pad consists of a single pulse to the contact pad. Using a single pulse may reduce an overall time of a test operation. In further embodiments, the pulsed exposure of a contact pad consists of multiple pulses. Multiple pulses and particularly respective measurements for obtaining information about an electric potential of the contact pad, may be used to reduce noise in the information about the one or more electric potentials.

In some embodiments, specifically when using an electrostatic subdeflector for positioning the electron beam in accordance with embodiments described herein, a positioning time for positioning the electron beam by the electrostatic subdeflector may be less than 200 ns, particularly less than 150 ns. For example, a positioning time may be about 100 ns.

In embodiments, obtaining information about an electric potential of each contact pad of the second plurality of contact pads includes, for each contact pad, detecting signal electrons 113 emitted from the contact pad, when the electron beam 111 is directed onto the contact pad, wherein the signal electrons 113 carry information about the electrical potential of the contact pad. The signal electrons 113 may be filtered by an energy filter and/or detected by an electron detector 140 as described herein to obtain the information about the one or more electric potentials of the second plurality of contact pads.

According to embodiments of the present disclosure, the method includes determining at least one defect of the packaging substrate 10 based on the information about one or more electric potentials of the second plurality of contact pads (block 206 in FIG. 2). For example, the information about one or more electric potentials of the second plurality of contact pads may indicate for each contact pad whether the contact pad is charged to the first electric potential or to the second electric potential. In some embodiments, determining the at least one defect includes determining a charged state of each contact pad of the second plurality of contact pads based on the respective information about the electric potential of each contact pad. In particular, the charged state may indicate whether the contact pad is charged to the first electric potential or to the second electric potential. In some embodiments, the charged state may be indicative of a high voltage contrast signal or a low voltage contrast signal. Determining the at least one defect may further include comparing the charged state of each contact pad of the second plurality of contact pads to a respective expected charged state of the contact pad, wherein a first expected charged state of the first plurality of contact pads is different from a further expected charged state of the further plurality of contact pads. The expected charged states of the contact pads may be predetermined, for instance based on a design of the packaging substrate including information on which contact pad belongs to which network. In embodiments, the at least one defect can be determined and/or classified based on a difference between the charged states of the contact pads and the expected charged states of the contact pads.

In embodiments, determining the at least one defect includes determining an open of the first large network and/or a short to the first large network, particularly a short from the one or more further networks to the first large network.

For example, referring back to FIG. 3C, the expected charged state of contact pad 333 is the same as for the other contact pads of the first plurality of contact pads 13, whose charged state is indicative of the first electric potential. However, the charged state determined based on information about the electric potential of the contact pad 333 is indicative of the second electric potential. Based on the difference between the determined charged state and expected charged state, an open 335 is determined in the first electrical interconnect path 15 leading to the contact pad 333. Similarly, the expected charged state of the contact pads 331 is the same as for the other contact pads of the further plurality of contact pads 23, whose charged state is indicative of the second electric potential. However, the charged state of the contact pads 331 is indicative of the first electric potential applied to the first large network. Based on the difference between determined charged state and expected charged state, a short 337 is determined between a first electrical interconnect path 15 and the further electrical interconnect path interconnecting the contact pads 331.

In a non-limiting example, a first electric potential may be a positive potential (e.g. +5 V), and the second electric potential may be a lower potential than the first electric potential (e.g. 0 V). With the first and second electric potentials provided according to embodiments described herein, and with the second plurality of contact pads including the first plurality of contact pads and the further plurality of contact pads, an open in the first large network can be indicated by a contact pad having a low voltage contrast signal instead of an expected high voltage contrast signal. A short to the first large network can be indicated by a contact pad having a high voltage contrast signal instead of an expected low voltage contrast signal.

In embodiments, the method may include flagging and/or processing a packaging substrate based on the determination of a defect, for instance flagging the packaging substrate for being discarded or for further review, if a defect is determined, or flagging the packaging substrate as non-defective, in which case the packaging substrate may, for example, be moved to ship the packaging substrate or to perform further processing operations on the packaging substrate.

Embodiments of the present disclosure may provide fast and reliable detection of defects, particularly of defects concerning the first large network. For instance, when testing tens of thousands or hundreds of thousands of contact pads, each pad may be tested in less than or in about 500 ns. According to an example, testing of 100,000 contact pads on one side of an approximately 60 mm×70 mm large packaging substrate in accordance with embodiments of the present disclose may take only about 50 ms, particularly when using a magnetic main deflector and an electrostatic subdeflector according to embodiments for positioning the electron beam via vector addressing. Using only the magnetic main deflector may add for instance 30 μs for each tested pad as compared to using the magnetic main deflector and the electrostatic subdeflector as described herein. Thus, testing of 100,000 pads may take significantly longer, such as about 3 s longer.

According to some embodiments of the present disclosure, a method may include more than a first test operation which relates to testing for defects related to the first large network and which may include, for example, the operations according to blocks 201 to 205 of FIG. 2. In particular, the packaging substrate includes one or more further networks, which may contain a defect, such as a short between two or more of the further networks, or an open in one of the one or more further networks. Such defects may remain undetected in a first test operation concerning defects related to the first large network. As illustrated in the flow diagram of FIG. 5, a method according to embodiments includes a first test operation (block 501). The first test operation may include for example the operations described in connection with blocks 201 to 206 of FIG. 2.

According to some embodiments, the method may include a second test operation (block 502 in FIG. 5) for testing a second large network. The second test operation may be performed analogously as for the first large network. The second test operation may particularly include operations in accordance with blocks 202-206 of FIG. 2, wherein the second large network takes the place of the first large network. In some embodiments, the first large network and particularly the first plurality of contact pads may be disregarded during the second test operation. In further embodiments, the first large network may be considered as one of the one or more further networks, and the first plurality of contact pads as part of the further plurality of contact pads. According to some embodiments, the method may additionally include a test operation analogous to the second test operation for at least one other large network of the packaging substrate.

Additionally, or alternatively to the second test operation, the method may optionally include a third test operation (block 503 in FIG. 5). The numbering of first, second and third does not indicate that a second test operation (block 502 in FIG. 5) would be required for performing the third test operation. For instance, the third test operation may also be referred to herein as a “second test operation”. In some embodiments, the test operations may be performed in the order of the numbering. In further embodiments, the numbering does not indicate an order of test operations. In embodiments, the one or more further networks may include a first small network, the first small network including a third plurality of contact pads having a small number of contact pads. The first small network may further include one or more second electrical interconnect paths for interconnecting the third plurality of contact pads.

In embodiments, the third test operation includes directing the electron beam onto a first small network contact pad of the third plurality of contact pads to charge the first small network to a third electric potential. Charging of a small network using the electron beam can be fast, reliable, and/or avoid scratching of the substrate surface or scratching of a contact pad as compared to contacting a contact pad via a mechanical contact. Further, for testing a multitude of small networks, sequentially charging and obtaining information about electric potentials can be faster than with a mechanical probe. In some embodiments, prior to charging the first small network, the third test operation may include charging the first large network and/or one or more other networks of the packaging substrate to a fourth electric potential, different from the third electric potential, e.g. via contactless charging according to embodiments described herein. A difference between the third electric potential and the fourth electric potential may be at least 1 V, particularly at least 2 V or at least 3 V, for example, approximately 5 V or similar to a difference between the first and second electric potentials.

According to embodiments, the third test operation includes obtaining information about one or more electric potentials of the third plurality of contact pads, wherein obtaining the information about one or more electric potentials includes directing the electron beam onto at least one second small network contact pad of the third plurality of contact pads and obtaining information about an electric potential of each of the at least one second small network contact pad. In some embodiments, obtaining information about one or more electric potentials may further include obtaining information about one or more electric potentials of at least one neighboring contact pad adjacent to a contact pad of the first small network, and/or obtaining information about one or more electric potentials of at least one contact pad connected to an interconnect path neighboring at least one of the one or more second electrical interconnect paths. In the third test operation, particularly both the “electrical driving” and the “probing” is done with an electron beam, such that defects can be reliably and quickly found. Testing by e-beam charging and e-beam probing (e.g., with an electron beam testing (EBT) column or an electron beam review (EBR) column) of small networks is independent of topography, fast, and flexible with regard to contact pad positions, size and geometry.

In embodiments, the third test operation includes determining at least one defect of the packaging substrate, particularly at least one defect related to the first small network, based on the information about one or more electric potentials of the third plurality of contact pads. In particular, the at least one defect may be determined based on the information about one or more electric potentials of the third plurality of contact pads, of the at least one neighboring contact pad and/or of the at least one contact pad connected to an interconnect path neighboring at least one of the one or more second electrical interconnect paths.

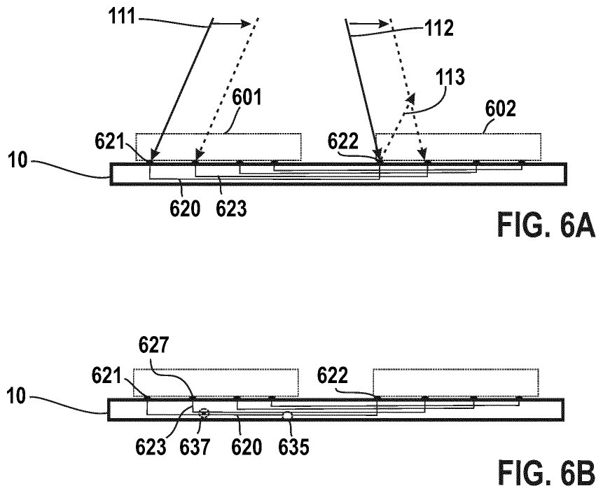

FIGS. 6A and 6B show enlarged sectional views of packaging substrates 10 during a third test operation according to embodiments described herein. The packaging substrates include a plurality of small networks. For instance, in FIGS. 6A and 6B, four small networks each having two contact pads interconnected by an electrical interconnect path are shown. In particular, the small networks include a first small network with a first small network contact pad 621, a second small network contact pad 622, and a second electrical interconnect path 620. For clarity, in FIGS. 6A and 6B, one or more large networks, particularly the first large network, are omitted for clarity. In the example of FIGS. 6A and 6B, the packaging substrate 10 may be an AP substrate or a PLP-substrate for the manufacture of a multi-die integrated package and includes a first die connection interface for attaching a first die 601 and a second die connection interface for attaching a second die 602.

In FIG. 6A, the second electrical interconnect path 620 extending between the first small network contact pad 621 and the second small network contact pad 622 is tested by directing a charging electron beam 111 on the first small network contact pad 621 to charge the first small network to the third electric potential. Then, the electron beam (denoted in FIG. 6A as electron beam 112) may be directed onto the second small network contact pad 622 for obtaining information about the electric potential of the second small network contact pad 622. The second small network contact pad 622 should be at the same electrical potential as the first small network contact pad 621. Signal electrons 113 emitted from the second small network contact pad 622 are detected that carry information about the electrical potential of the second small network contact pad 622. If an electrical potential of the second small network contact pad 622 is determined to be different from the electrical potential of the first small network contact pad 621, a defect is detected. For instance, in FIG. 6B, an open 635 exists in the second electrical interconnect path 620. The open 635 is determined because the second small network contact pad 622 is not charged after or during the charging of the first small network contact pad 621 by the charging electron beam 111.

After probing the contact pads of the first small network, the electron beam 111 can be directed on further contact pads such as further contact pads neighboring the first or second small network contact pads 621, 622, and/or further contact pads connected to a further electrical interconnect path neighboring the second electrical interconnect path 620. In FIG. 6B, a short 637 exists between the second electrical interconnect path 620 and a further electrical interconnect path 623. The short can be determined because the further electrical interconnect path 623 is charged together with the second electrical interconnect path 620, which can be detected by the probing electron beam that is directed on the further contact pad 627 after, or during, the charging of the first small network. For an evaluation and defect classification, the signals of measurements of neighboring interconnect paths and/or previously collected data can be compared, such that opens and/or shorts in the packaging substrate can be identified.

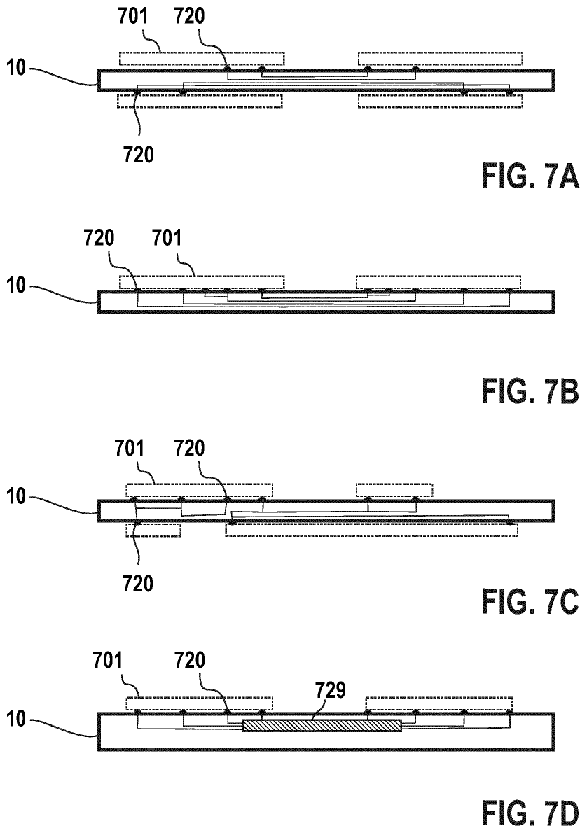

FIGS. 7A to 7D show enlarged sectional views of non-limiting examples of packaging substrates 10 that can be tested according to the methods described herein. The packaging substrates may be configured for the mounting of devices or dies 701 to be connected via the electrical networks of the packaging substrates.

The packaging substrate 10 depicted in FIG. 7A has surface contact pads on both main surfaces of the packaging substrate 10. For example, a plurality of device-to-device electrical interconnect paths may extend between contact pads exposed on an upper substrate surface, and a further plurality of device-to-device electrical interconnect paths may extend between contact pads exposed on a lower substrate surface.

The packaging substrate 10 depicted in FIG. 7B has at least one device-to-device electrical interconnect paths that extend between contact pads on a first side of the packaging substrate 10.

The packaging substrate 10 depicted in FIG. 7C has at least one device-to-device electrical interconnect path that extends between contact pads 720 that are exposed on different main surfaces of the packaging substrate 10 in a complex connection network, for instance a large network as described herein. Such a device-to-device electrical interconnect path may be configured for connecting three or more dies with each other through the packaging substrate. Additionally or alternatively, one or more device-to-device electrical interconnect paths may be configured for making contact between dies at a top surface of the packaging substrate, and a ball grid array or contact pins at the bottom of the packaging substrate through the packaging substrate.

The packaging substrate 10 depicted in FIG. 7D has at least one interconnect bridge 729 embedded in the packaging substrate 10. At least one device-to-device electrical interconnect path extends through the at least one interconnect bridge 729. In particular, a plurality of device-to-device electrical interconnect paths extending between a first die connection interface and a second die connection interface of the packaging substrate 10, extend through the interconnect bridge 729. The interconnect bridge 729 may be embedded in the packaging substrate 10 during the manufacture of the packaging substrate 10. The interconnect bridge 729 may be a bridge chip embedded in the packaging substrate 10 for increasing the connection speed between multiple dies.

Embodiments of the present disclosure may particularly provide fast and reliable testing of packaging substrates having at least one large network, particularly in a review process of the packaging substrate. More specifically, large networks may have a relatively high capacitance. Charging a large network using an electron beam may involve a long charging time. Embodiments may provide for fast charging of a large network using a voltage source and fast “reading” of contact pads for obtaining information about the respective electric potentials, using an electron beam in order to determine a defect. Further, small networks of the packaging substrate may be tested contactlessly in a fast and reliable manner, particularly by charging and reading contact pads using one or more electron beams. Embodiments of the present disclosure may use a main deflector and a subdeflector, specifically a magnetic main deflector and an electrostatic subdeflector, for fast and precise positioning of the electron beam onto the contact pads. Positioning the electron beam on the contact pads via vector addressing may provide fast and direct addressing of the contact pads, particularly avoiding raster scanning over the substrate body and/or reducing a charge deposited by the electron beam on the substrate body. Testing of packaging substrates according to embodiments, for instance testing of 100,000 contact pads on a large packaging substrate in about 50 ms for defects related to a large network, may speed up a review process after and/or during fabrication of a packaging substrate. Embodiments may advantageously increase throughput in reviewing packaging substrates, improve reliability of the review process and/or reduce costs of the review process.

While the foregoing is directed to some embodiments, other and further embodiments may be devised without departing from the basic scope thereof, and the scope thereof is determined by the claims that follow.

1. A method for testing a packaging substrate with at least one electron beam column, the method comprising a first test operation, wherein the first test operation comprises:
positioning the packaging substrate in a vacuum chamber;
connecting a voltage source to one or more first contact pads of a first large network of the packaging substrate, the first large network comprising a first plurality of contact pads having a large number of contact pads, the first large network further comprising first electrical interconnect paths for interconnecting the first plurality of contact pads;
applying a first electric potential to the one or more first contact pads using the voltage source;
charging one or more further networks of the packaging substrate to a second electric potential different from the first electric potential, wherein the one or more further networks comprise a further plurality of contact pads;
obtaining information about one or more electric potentials of a second plurality of contact pads comprising the further plurality of contact pads, wherein obtaining the information about one or more electric potentials comprises directing an electron beam of the at least one electron beam column via vector addressing onto each of the second plurality of contact pads and obtaining information about an electric potential of each of the second plurality of contact pads; and
determining at least one defect of the packaging substrate based on the information about one or more electric potentials of the second plurality of contact pads.

2. The method of claim 1, wherein the second plurality of contact pads further comprises the first plurality of contact pads.

3. The method of claim 1, wherein connecting the voltage source to the one or more first contact pads of the first large network comprises providing a mechanical contact between the voltage source and the one or more first contact pads.

4. The method of claim 1, wherein charging the one or more further networks to the second electric potential comprises contactless charging the one or more further networks to the second electric potential.

5. The method of claim 4, wherein contactless charging the one or more further networks is performed by exposing the further plurality of contact pads of the one or more further networks to at least one of vacuum ultraviolet light, electrons of a flood gun, an electron beam, or an ion beam.

6. The method of claim 1, wherein the first plurality of contact pads comprises at least 10 contact pads.

7. The method of claim 1, wherein the second plurality of contact pads comprises all contact pads of the packaging substrate arranged on the same side of the packaging substrate as the further plurality of contact pads.

8. The method of claim 1, wherein the at least one electron beam column comprises a magnetic main deflector and an electrostatic subdeflector, and wherein obtaining information about one or more electric potentials of the second plurality of contact pads comprises:
dividing a surface area of the packaging substrate, the surface area comprising the second plurality of contact pads, into a plurality of subfields; and
sequentially directing the electron beam to each of the plurality of subfields using the magnetic main deflector, and, when the electron beam is positioned in a subfield by the magnetic main deflector, directing the electron beam using the electrostatic subdeflector to each contact pad of the second plurality of contact pads within the subfield for obtaining information about the electric potential of each contact pad in the subfield.

9. The method of claim 1, wherein each of the plurality of subfields has a size of at least one of minimum 0.1 mm² or maximum 30 mm².

10. The method of claim 1, wherein the electron beam is directed onto each contact pad of the second plurality of contact pads for a pulsed exposure of the contact pad to the electron beam for obtaining the information about the electric potential of the contact pad.

11. The method of claim 1, wherein the at least one defect comprises at least one of an open of the first large network and/or a short to the first large network.

12. The method of claim 1, wherein determining the at least one defect comprises determining a charged state of each contact pad of the second plurality of contact pads based on the respective information about the electric potential of each contact pad, and comparing the charged state of each contact pad of the second plurality of contact pads to a respective expected charged state of the contact pad, wherein a first expected charged state of the first plurality of contact pads is different from a further expected charged state of the further plurality of contact pads.

13. The method of claim 1, wherein the one or more further networks comprise a first small network comprising a third plurality of contact pads having a small number of contact pads, the first small network further comprising one or more second electrical interconnect paths for interconnecting the third plurality of contact pads, the method further comprising a second test operation, the second test operation comprising:
directing the electron beam onto a first small network contact pad of the third plurality of contact pads to charge the first small network to a third electric potential;
obtaining information about one or more electric potentials of the third plurality of contact pads, wherein obtaining the information about one or more electric potentials comprises directing the electron beam onto at least one second small network contact pad of the third plurality of contact pads and obtaining information about an electric potential of each of the at least one second small network contact pad;
determining at least one defect of the packaging substrate based on the information about one or more electric potentials of the third plurality of contact pads.

14. An apparatus configured for testing a packaging substrate, the apparatus comprising:
a stage for arranging the packaging substrate;
at least one electron beam column for providing an electron beam; a voltage source configured to be connected to a contact pad of the packaging substrate;
a computer-readable medium containing a program for testing the packaging substrate, which, when executed by a processor, performs a method, comprising:
positioning the packaging substrate in a vacuum chamber;
connecting a voltage source to one or more first contact pads of a first large network of the packaging substrate, the first large network comprising a first plurality of contact pads having a large number of contact pads, the first large network further comprising first electrical interconnect paths for interconnecting the first plurality of contact pads;
applying a first electric potential to the one or more first contact pads using the voltage source;
charging one or more further networks of the packaging substrate to a second electric potential different from the first electric potential, wherein the one or more further networks comprise a further plurality of contact pads;
obtaining information about one or more electric potentials of a second plurality of contact pads comprising the further plurality of contact pads, wherein obtaining the information about one or more electric potentials comprises directing an electron beam of the at least one electron beam column via vector addressing onto each of the second plurality of contact pads and obtaining information about an electric potential of each of the second plurality of contact pads; and
determining at least one defect of the packaging substrate based on the information about one or more electric potentials of the second plurality of contact pads.

15. A non-transitory computer-readable medium including instructions, which, when executed by a processor of an apparatus configured for testing a packaging substrate, cause the apparatus to perform a method, comprising:
positioning the packaging substrate in a vacuum chamber;
connecting a voltage source to one or more first contact pads of a first large network of the packaging substrate, the first large network comprising a first plurality of contact pads having a large number of contact pads, the first large network further comprising first electrical interconnect paths for interconnecting the first plurality of contact pads;
applying a first electric potential to the one or more first contact pads using the voltage source;
charging one or more further networks of the packaging substrate to a second electric potential different from the first electric potential, wherein the one or more further networks comprise a further plurality of contact pads;
obtaining information about one or more electric potentials of a second plurality of contact pads comprising the further plurality of contact pads, wherein obtaining the information about one or more electric potentials comprises directing an electron beam of the at least one electron beam column via vector addressing onto each of the second plurality of contact pads and obtaining information about an electric potential of each of the second plurality of contact pads; and
determining at least one defect of the packaging substrate based on the information about one or more electric potentials of the second plurality of contact pads.

16. The method of claim 1, wherein the second plurality of contact pads further comprises the first plurality of contact pads; and wherein the at least one defect comprises at least one of an open of the first large network or a short to the first large network.

17. The method of claim 1, wherein the first plurality of contact pads comprises at least 500 contact pads.

18. The method of claim 10, wherein the pulsed exposure of a contact pad consists of a single pulse.
